(19) United States
(12) Patent Application Publication
(10) Pub. No.: US 2025/0048857 A1
(43) Pub. Date: Feb. 6, 2025

(54) DISPLAY ELEMENT AND ELECTRONIC DEVICE

(71) Applicant: SONY SEMICONDUCTOR SOLUTIONS CORPORATION, KANAGAWA (JP)

(72) Inventor: AKIYOSHI AOYAGI, KANAGAWA (JP)

(21) Appl. No.: 18/719,928

(22) PCT Filed: Nov. 18, 2022
(86) PCT No.: PCT/JP2022/042855

§ 371 Date: Jun. 14, 2024

(30) Foreign Application Priority Data
Dec. 23, 2021 (JP) 2021-209646

(51) Int. Cl. H10K 59/127; H10K 59/131; H10K 59/95

(52) U.S. Cl. CPC H10K 59/1275; H10K 59/131; H10K 59/95

(57) ABSTRACT

The present disclosure provides a display element that is capable of reducing the area of a substrate including light emitting elements and has an enhanced stability of connection of a drive integrated circuit to the substrate and a flexible substrate, and also provides an electronic device using the display element. The display element includes: a substrate that includes a light emitting element disposed therein, and has a light emitting surface; a drive integrated circuit including a drive circuit that controls driving of the light emitting element; and a flexible substrate having a connecting terminal. In the display element, the drive integrated circuit is disposed on one surface of the substrate, and the flexible substrate is disposed on the side of a surface of the drive integrated circuit, the surface not facing the substrate.

### TECHNICAL FIELD

The present disclosure relates to a display element and an electronic device.

### BACKGROUND ART

A known display element includes a substrate having light emitting elements on a base substrate, and further includes a drive integrated circuit and a flexible substrate (flexible integrated circuit; FPC) disposed on the same surface of the substrate. In such a display element, the area of the substrate is required to be sufficiently large to ensure the region for accommodating the drive integrated circuit and the flexible substrate, in addition to the region for accommodating the light emitting elements. Therefore, there is room for improvement in the display element, in terms of a smaller area for the substrate including the light emitting elements.

An electro-optical device disclosed in Patent Document 1 includes: an electro-optical panel in which a plurality of EL elements is arranged; an IC element that is connected to the electro-optical panel and includes a circuit for driving or controlling the EL elements; and an FPC on which the IC is mounted, and wiring lines electrically connected to the circuit in the IC element are provided. The IC element in the electro-optical device has first terminal pads connected to the wiring lines on the FPC, and second terminal pads connected to the wiring lines on the electro-optical panel.

### CITATION LIST

### Patent Document

Patent Document 1: Japanese Patent Application Laid-Open No. 2006-244888

### SUMMARY OF THE INVENTION

### Problems to be Solved by the Invention

In the electro-optical device disclosed in Patent Document 1, dimensional accuracy is required for the first terminal pads and the second terminal pads. Further, to stabilize a state in which the FPC and the IC element are pressure-bonded to the electro-optical panel with an anisotropic conductive film, it is required to consider the difference in elastic modulus between the FPC and the IC element. Therefore, in the electro-optical device disclosed in Patent Document 1, there is room for improvement in the stability of connection of the IC element to both the electro-optical panel and the FPC.

The present disclosure has been made in view of the aspects described above, and an object of the present disclosure is to provide a display element that is capable of reducing the area of a substrate including light emitting elements and has an enhanced stability of connection of a drive integrated circuit to the substrate and a flexible substrate, and an electronic device using the display element.

### Solutions to Problems

The present disclosure relates to, for example,
(1) a display element including:
a substrate that includes a light emitting element disposed therein, and has a light emitting surface;
a drive integrated circuit including a drive circuit that controls driving of the light emitting element; and a flexible substrate, in which the drive integrated circuit is disposed on one surface of the substrate, and the flexible substrate is disposed on a surface of the drive integrated circuit, the surface not facing the substrate.

The present disclosure also relates to
(2) a display element including:
a substrate that includes a light emitting element disposed therein, and has a light emitting surface;
a drive integrated circuit including a drive circuit that controls driving of the light emitting element; and
a flexible substrate,
in which the drive integrated circuit is disposed on one surface of the substrate, and
the flexible substrate is disposed on a surface of the substrate, the surface being opposite to the light emitting surface.

The present disclosure may relates to
(3) a display element including:
a substrate that includes a light emitting element disposed therein, and has a light emitting surface;
a drive integrated circuit including a drive circuit that controls driving of the light emitting element; and
a conductive connecting member that relays electrical connection with outside,
in which the drive integrated circuit is disposed on one surface of the substrate, and
the conductive connecting member is disposed on a surface of the drive integrated circuit, the surface not facing the substrate.

The present disclosure may also relates to, for example, (4) an electronic device including the above display device of (1).

### BRIEF DESCRIPTION OF DRAWINGS

FIG. 1 is an exploded perspective view for explaining an example of a display device according to a first embodiment.

FIG. 2 is a cross-sectional view for explaining an example of the display device according to the first embodiment.

FIG. 3 is a cross-sectional view for explaining an example of a drive circuit in an example of the display device according to the first embodiment.

FIG. 4 is a cross-sectional view for explaining an example of a display device according to a second embodiment.

FIG. 5 is a cross-sectional view for explaining an example of a display device according to a third embodiment.

FIG. 6 is a cross-sectional view for explaining an example of a display device according to a fourth embodiment.

FIG. 7 is a cross-sectional view for explaining an example of a display device according to a fifth embodiment.

FIG. 8 is a cross-sectional view for explaining an example of a display device according to a modification of the fifth embodiment.

FIG. 9 is a plan view for explaining an example of a display device according to a sixth embodiment.

FIGS. 10A and 10B are diagrams for explaining an example of an electronic device using a display device.

FIG. 11 is a diagram for explaining an example of an electronic device using a display device.

FIG. 12 is a diagram for explaining an example of an electronic device using a display device.

### MODE FOR CARRYING OUT THE INVENTION

In the description below, an example and the like according to the present disclosure will be described with reference to the drawings. Note that explanation will be made in the following order. In the present specification and the drawings, components having substantially the same functional configurations are denoted by the same reference signs, and explanation of them will not be repeated.

Note that the explanation will be made in the following order.
1. First Embodiment
2. Second Embodiment
3. Third Embodiment
4. Fourth Embodiment
5. Fifth Embodiment
6. Sixth Embodiment
7. Example Applications

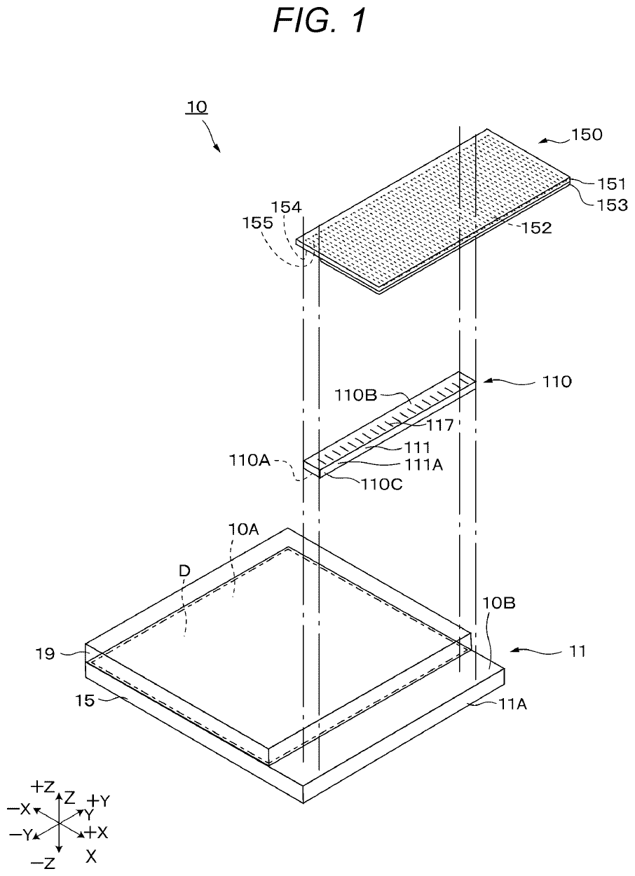

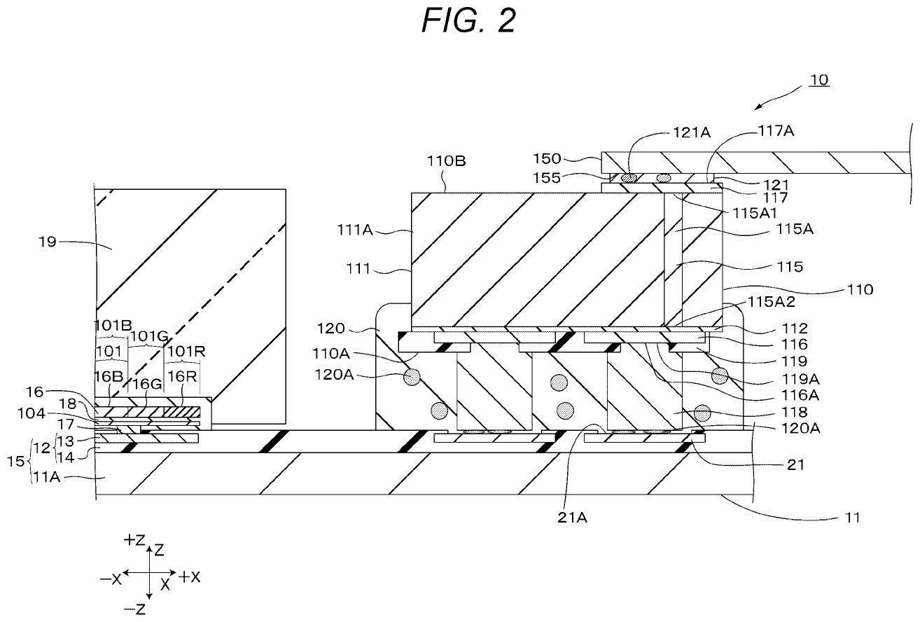

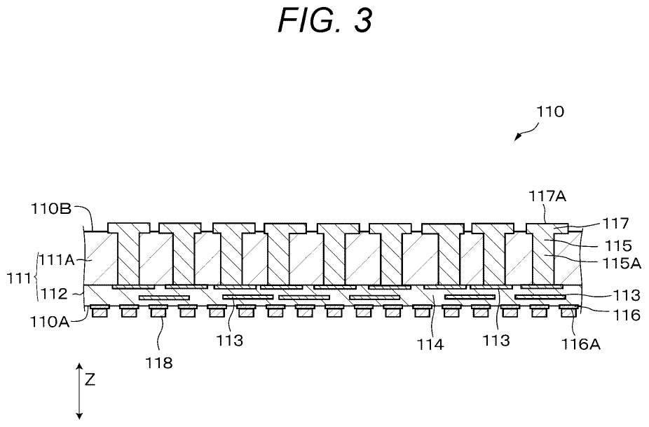

The following description concerns preferred specific examples of the present disclosure, and the contents of the present disclosure are not limited to these embodiments and the like. Also, in the following description, directions such as forward and backward, rightward and leftward, and upward and downward directions are used for ease of explanation, but the contents of the present disclosure are not limited by these directions. In examples in FIGS. 1 and 2, it is assumed that the Z-axis direction is the upward and downward directions (the upper side is the +Z direction, and the lower side is the −Z direction), the X-axis direction is the forward and backward directions (the front side is the +X direction, and the back side is the −X direction), and the Y-axis direction is the rightward and leftward directions (the right side is the +Y direction, and the left side is the −Y direction). The explanation will be made on the basis of these directions. The same applies in FIGS. 3 to 9. A relative dimensional ratio of the size and thickness of each layer illustrated in each drawing of FIG. 1 and the like is shown for convenience, and does not limit any actual dimensional ratio. This applies in each drawing of FIGS. 2 to 9 regarding the definitions of these directions and the dimensional ratios.

Examples of display elements according to the present disclosure include a display module, an illumination module, and the like. In the following first to sixth embodiments, cases where a display element is a display module will be described.

In a display element according to the present disclosure, a light emitting element provided in the display region described later is not limited to any particular light emitting element, and examples thereof include a light emitting diode (LED), an organic light emitting diode (OLED), and the like. In the following first to sixth embodiments, cases where a light emitting element is an OLED will be described as examples. In the present disclosure, an OLED is referred to as an organic electroluminescence (EL) element in some cases. Further, a display element including an OLED as a light emitting element is referred to as an organic EL display element in some cases.

### 1 First Embodiment

### [1-1 Configuration of a Display Element]

An organic EL (OLED) display element (hereinafter referred to simply as a “display element 10”) as an example of a display element according to an embodiment of the present disclosure is described below with reference to FIGS. 1 and 2 and others. FIG. 1 is an exploded perspective view illustrating an example configuration of the display element 10. FIG. 2 is a cross-sectional view for explaining the display element. As illustrated in FIGS. 1 and 2, the display element 10 includes a substrate 11 that has a light emitting element 104 and a light emitting surface D.

### (Display Region and Outer Region)

In the display element 10, a light emitting region 10A and an outer region 10B are defined on the side of the light emitting surface D. The light emitting region 10A is defined as the region where light generated from a plurality of light emitting elements 104 is emitted to the outside. The outer region 10B is defined as a region outside the light emitting region 10A on the surface of the substrate 11 on the side of the light emitting surface D. In the example in FIG. 1, the light emitting region 10A is formed as a rectangular region, and the region defined as a rectangular annular region outside the light emitting region 10A is the outer region 10B. The position of the outer edge of the light emitting region 10A is the position of the inner peripheral edge of the outer region 10B, and the light emitting region 10A and the outer region 10B are in contact with each other at the boundary. Note that, among the surfaces of the substrate 11, the light emitting surface D indicates the surface from which light generated from the light emitting elements 104 is extracted to the outside in the display element 10.

In the description below, a case where the display element 10 performs display by a top emission method is explained as an example. The top emission method indicates a method by which the light emitting elements 104 are disposed on the side of the light emitting surface D rather than the side of a base substrate 11A. Accordingly, in the display element 10, the base substrate 11A is located on the back surface side of the display element 10, and the direction (+Z direction) from the base substrate 11A toward the light emitting elements 104 described later is the direction toward the front surface side (upper surface side) of the display element 10. In the display element 10, light generated from the light emitting elements 104 is directed in the +Z direction, and is emitted to the outside. In the description below, in each of the layers constituting the display element 10, the surface on the display surface side in the display region (light emitting region 10A) of the display element 10 will be referred to as the first surface (upper surface), and the surface on the back surface side of the display element 10 will be referred to as the second surface (lower surface). Note that this does not prohibit any case where the display element 10 according to the present disclosure is of a bottom emission type. The display element 10 is also applicable to a bottom emission type. By a bottom emission method, light generated from the light emitting elements 104 is directed in the −Z direction, and is emitted to the outside.

### (Configuration of Sub-Pixels)

In the example of the display element 10 illustrated in FIG. 1, one pixel is formed with a combination of a plurality of sub-pixels corresponding to a plurality of color types. In this example, the three colors of red, green, and blue are defined as the plurality of color types, and the three types of sub-pixel 101R, sub-pixel 101G, and sub-pixel 101B are provided as sub-pixels. The sub-pixel 101R, the sub-pixel 101G, and the sub-pixel 101B are a red sub-pixel, a green sub-pixel, and a blue sub-pixel, respectively, and display the red color, the green color, and the blue color, respectively. However, the example in FIG. 1 is an example, and does not limit the color types of the plurality of sub-pixels. Further, the wavelengths of light beams corresponding to the respective color types of red, green, and blue can be determined as wavelengths in the range of 610 nm to 650 nm, the range of 510 nm to 590 nm, and the range of 440 nm to 480 nm, respectively, for example. Furthermore, examples of layouts of the individual sub-pixels 101R, 101G, and 101B include a layout in which combinations of sub-pixels 101 formed in a striped shape are arranged in a matrix. In the example in FIG. 1, the sub-pixels 101R, 101G, and 101B are two-dimensionally disposed in the light emitting region 10A.

In the description below, the term “sub-pixels 101” is used in a case where the sub-pixels 101R, 101G, and 101B are not particularly distinguished from one another.

### (Substrate)

The substrate 11 (hereinafter also referred to as the principal board) includes a circuit board 15 in which a circuit layer 12 for driving a plurality of light emitting elements 104 is provided on the base substrate 11A, and the plurality of light emitting elements 104 on the circuit board 15.

### (Circuit Layer)

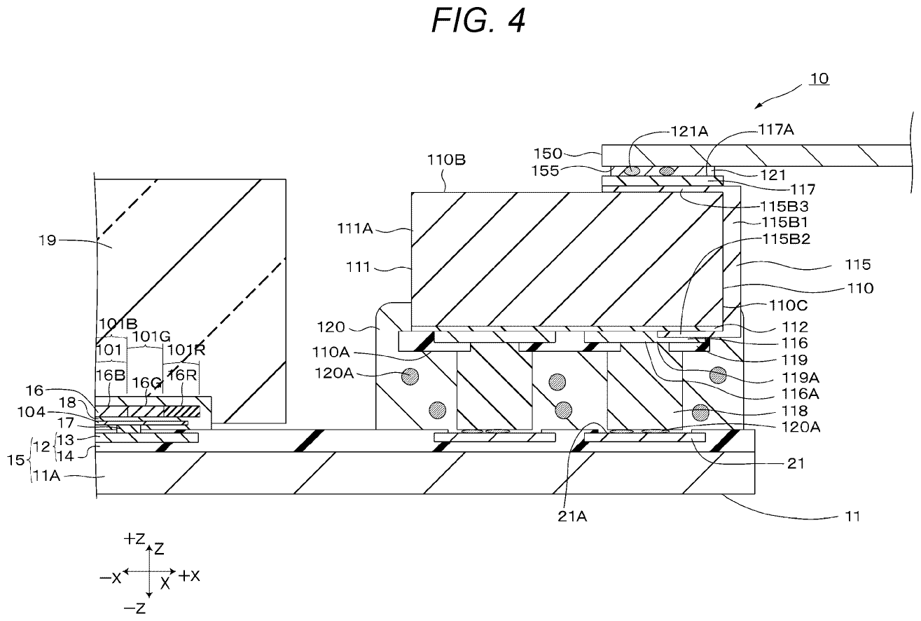

The circuit layer 12 formed on the circuit board 15 forming the principal board includes a circuit structure 13 forming a circuit, and an insulating layer 14. Examples of the circuit formed by the circuit structure 13 include a control circuit that controls driving of the light emitting elements 104, and a power supply circuit that supplies power to the plurality of light emitting elements 104 (neither the control circuit nor the power supply circuit is shown in the drawings). In FIG. 2, for ease of explanation, the circuit structure 13 is comprehensively illustrated as one layer. The circuit board 15 forming the substrate 11 as the principal board corresponds to a so-called backplane. This also applies in FIGS. 4 to 9.

### (Base Substrate)

The base substrate 11A may be formed with glass or resin having low moisture and oxygen permeability, or may be formed with a semiconductor in which a transistor or the like is easily formed, for example. Specifically, the base substrate 11A may be a glass substrate, a semiconductor substrate, a resin substrate, or the like. The glass substrate contains high strain point glass, soda glass, borosilicate glass, forsterite, lead glass, quartz glass, or the like, for example. The semiconductor substrate contains amorphous silicon, polycrystalline silicon, monocrystalline silicon, or the like, for example. The resin substrate contains at least one material selected from the group consisting of polymethyl methacrylate, polyvinyl alcohol, polyvinyl phenol, polyethersulfone, polyimide, polycarbonate, polyethylene terephthalate, polyethylene naphthalate, and the like, for example.

A plurality of contact plugs 17 for connecting the light emitting elements 104 and the circuit in the circuit structure 13 of the circuit layer 12 is provided on the first surface of the base substrate 11A. The insulating layer 14 is formed around the circuit structure 13 and the contact plugs 17 formed on the base substrate 11A.

### (Insulating Layer)

The insulating layer 14 is formed with an organic material or an inorganic material, for example. The organic material contains at least one material of polyimide or acrylic resin, for example. The inorganic material contains at least one material of silicon oxide, silicon nitride, silicon oxynitride, and aluminum oxide, for example.

### (Contact Plugs)

A contact plug 17 can be formed as a portion in which a conductive structure is formed in a hole portion formed in the insulating layer 14, for example. The contact plug 17 make the light emitting element 104 and the circuit structure 13 electrically continuous with each other. In the conductive structure, a layer of a conductive material is formed on the inner peripheral surface of the hole portion in some cases, and the hole portion is filled with a conductive material in other cases. As the conductive material, a conductive material that is similar to the conductive material forming a through hole 115A to be the first conductive structure 115 described later can be used. In FIG. 2, a contact plug 17 is formed for each pixel, for ease of explanation. However, a contact plug 17 is preferably formed for each sub-pixel 101.

### (Light Emitting Elements)

In the display element 10, a plurality of light emitting elements 104 is disposed on the first surface side of the substrate 11. In the examples in FIG. 2 and others, the light emitting elements 104 are organic electroluminescence elements (organic EL elements or OLED elements). Also, in the example in FIG. 2, for ease of explanation, the plurality of light emitting elements 104 is formed for each pixel. However, the plurality of light emitting elements 104 is normally provided for each sub-pixel so as to correspond to the individual sub-pixels 101R, 101G, and 101B. The plurality of light emitting elements 104 is two-dimensionally arranged in a prescribed arrangement pattern such as a matrix form or the like, for example.

The light emitting elements 104 each include a first electrode, an organic layer, and a second electrode (not shown in the drawings). The first electrode, the organic layer, and the second electrode are stacked in this order from the side of the base substrate 11A in the direction from the second surface toward the first surface.

### (First Electrode)

A plurality of first electrodes is provided on the side of the first surface of the base substrate 11A. The first electrodes are electrically connected to the contact plugs 17 (not illustrated). The first electrodes are connected for the respective sub-pixels 101. The first electrodes are electrically separated from each other for the respective sub-pixels 101 by an insulating layer described later. The first electrodes are anode electrodes. The first electrodes each include at least one of a metal layer or a metal oxide layer. The first electrodes may each include a single layer film of a metal layer or a metal oxide layer, or a film stack of a metal layer and a metal oxide layer.

The metal layer contains at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag), for example. The metal layer may contain the at least one metal element described above as a constituent element of an alloy. Specific examples of the alloy include an aluminum alloy and a silver alloy. Specific examples of the aluminum alloy include AlNd and AlCu, for example.

The metal oxide layer contains at least one of a mixture of indium oxide and tin oxide (ITO), a mixture of indium oxide and zinc oxide (IZO), or titanium oxide (TiO), for example.

### (Organic Layer)

The organic layer is disposed between the first electrode and the second electrode. The organic layer may be provided as a layer common to the sub-pixels 101, or may be provided as an independent layer for each of the sub-pixels 101R, 101G, and 101B. As the organic layer, an organic layer that generates red light, an organic layer that generates blue light, an organic layer that generates green light, or the like may be adopted in accordance with the sub-pixel 101R, 101G, or 101B. Alternatively, in a case where the organic layer is a layer common to the sub-pixels 101, an organic layer that generates white light may be adopted as the organic layer, for example.

The organic layer has a configuration in which a hole injection layer, a hole transport layer, a light emitting layer, and an electron transport layer are stacked in this order in the direction from the first electrode toward the second electrode, for example. An electron injection layer may be disposed between the electron transport layer and the second electrode. The electron injection layer is for enhancing electron injection efficiency. Note that the configuration of the organic layer is not limited to this, and layers other than the light emitting layer are provided as necessary. The hole injection layer is a buffer layer for enhancing efficiency of hole injection into the light emitting layer and reducing leakage. The hole transport layer is for enhancing efficiency of hole transport to the light emitting layer. The electron transport layer is for enhancing efficiency of electron transport to the light emitting layer.

The light emitting layer generates light when recombination of electrons and holes is caused by an electric field. The light emitting layer is an organic light emitting layer containing an organic light emitting material.

### (Second Electrode)

In the light emitting element 104, the second electrode is disposed to face the first electrode. The second electrode may be provided for each sub-pixel 101, or may be provided as an electrode common to a plurality of sub-pixels 101. The second electrode is a cathode electrode. The second electrode is preferably a transparent electrode having transparency to light generated in the organic layer. The transparent electrode herein may be a transparent electrode formed with a transparent conductive layer, or a transparent electrode formed with a stack structure including a transparent conductive layer and a semi-transmissive reflective layer.

The transparent conductive layer can be formed with a metal oxide, for example. Specifically, an example of the material of the transparent conductive layer can be a material containing at least one of a mixture of indium oxide and tin oxide (ITO), a mixture of indium oxide and zinc oxide (IZO), or zinc oxide (ZnO).

The semi-transmissive reflective layer can be formed with a metal layer, for example. Specifically, examples of the material of the semi-transmissive reflective layer can include a material including at least one metal element selected from the group consisting of magnesium (Mg), aluminum (Al), silver (Ag), gold (Au), and copper (Cu). The metal layer may contain the at least one metal element described above as a constituent element of an alloy. Specific examples of the alloy include an MgAg alloy, an AgPdCu alloy, and the like.

### (Protective Layer)

As illustrated in FIG. 2, a protective layer 18 is formed so as to cover the first surfaces of the light emitting elements 104. The protective layer 18 shields the light emitting elements 104 from the outside air, and reduces moisture infiltration into the light emitting elements 104 from the external environment.

The protective layer 18 is formed with an insulating material. As the insulating material, thermosetting resin or the like can be used, for example. Other than that, the insulating material may be SiO, SiON, AlO, TiO, or the like. In this case, examples of the protective layer 18 include a CVD film containing Sio, SiON, or the like, and an ALD film containing AlO, TiO, SiO, or the like. Note that a CVD film means a film formed by chemical vapor deposition. An ALD film means a film formed by atomic layer deposition. Note that, in FIG. 2, for ease of explanation, the protective layer 18, the insulating layer formed between the adjacent first electrodes, and the layer filling the gap between color filters 16 and a counter substrate 19 are described as an integrated layer structure. That is, as illustrated in FIG. 2, the protective layer 18 is also formed on the second surface side of the light emitting elements 104, and is also formed between the color filters 16 and the counter substrate 19.

### (Color Filters)

The color filters 16 may be provided on the light emitting elements 104, as necessary. In the example in FIG. 2, the color filters 16 corresponding to the color types of the sub-pixels 101 are provided. In a sub-pixel 101R, a red-color filter 16R is provided as the color filter 16. In a sub-pixel 101G, a green-color filter 16G is provided as the color filter 16. In a sub-pixel 101B, a blue-color filter 16B is provided as the color filter 16. Also, lenses or the like may be further provided. Note that a layer structure similar to that of the protective layer 18 may also be formed between the color filters 16 and the counter substrate 19.

### (Counter Substrate)

As illustrated in the examples in FIGS. 1 and 2 and others, the counter substrate 19 may be provided on the first surface side of the light emitting elements 104. As the material of the counter substrate 19, the material of the base substrate 11A of the substrate 11 or the like can be used. For example, a glass substrate can be used as the counter substrate 19. The material of the glass substrate is not limited to any particular material, as long as the glass substrate is formed with a material that transmits light emitted from the organic layer. Examples of the material of the glass substrate include various glass substrates such as high strain point glass, soda glass, borosilicate glass, and lead glass, and quartz substrates.

### (Electrode Pads on the Substrate Side)

Electrode pads 21 electrically connected to the drive integrated circuit 110 described later are formed on the first surface side of the substrate 11. The electrode pads 21 on the side of the substrate 11 are provided so as to be electrically connectable to the drive integrated circuit 110 at a position where the drive integrated circuit 110 is disposed in the outer region 10B in a planar view of the substrate 11. Each electrode pad 21 is formed in a layer-like form in the example in FIG. 2. Such electrode pads 21 can be formed by a sputtering method and an etching method, for example. The material of the electrode pads 21 connected to the drive integrated circuit 110 can be formed with a conductive material, for example. Examples of the conductive material include metal materials such as copper, aluminum, and silver. The electrode pads 21 are provided in the insulating layer 14 disposed on the base substrate 11A. Further, at least a partial region (an exposed surface 21A) of each electrode pad 21 is exposed on the upper surface side (the same surface side as the light emitting surface D) of the electrode pad 21. On the exposed surface 21A of the electrode pad 21, the electrode pad 21 is electrically connected to the drive integrated circuit 110 described later, as illustrated in FIG. 2. In the example in FIG. 2, the electrode pads 21 are electrically connected to the drive integrated circuit 110 via projecting electrodes 118.

### (Drive Integrated Circuit)

The display element 10 includes the drive integrated circuit 110 on one surface side of the substrate 11. In the examples in FIGS. 1 and 2, the drive integrated circuit 110 is provided on the side of the light emitting surface D of the substrate 11. The drive integrated circuit 110 is an integrated circuit (IC) in which a drive circuit that controls driving of the light emitting elements 104 is formed. In the examples in FIGS. 1, 2, and 3, the drive integrated circuit 110 is a display driver integrated circuit (DDIC) that controls driving of the circuit of the substrate 11. The DDIC controls a light-emitting state of the light emitting surface D. In the examples in FIG. 1 and others, the drive integrated circuit 110 is disposed in the outer region 10B.

In the example in FIG. 3, the drive integrated circuit 110 includes a substrate 111 (sometimes referred to as a sub board) having a structure in which a drive circuit layer 112 is formed on a base substrate 111A. That is, the substrate 111 is a substrate on which a drive circuit formed in the drive circuit layer 112 is mounted. As the base substrate 111A, a glass substrate, a semiconductor substrate, a resin substrate, or the like may be used, like the base substrate 11A forming the substrate 11. As the base substrate 111A, a silicon substrate or the like can be suitably used.

As illustrated in FIG. 3, the drive circuit layer 112 has a structure in which a drive circuit is disposed inside the insulating layer 114. FIG. 3 shows wiring lines 113 that constitute the drive circuit, for example. As the material of the insulating layer 114, a material similar to the insulating layer 14 provided on the base substrate 11A may be used.

### (First Conductive Structures)

Conductive structures that relay electrical connection with a flexible substrate 150 are provided in the drive integrated circuit 110. The conductive structures ire referred to as first conductive structures 115. The first conductive structures 115 electrically connect the drive circuit of the drive integrated circuit 110 and the circuit of the flexible substrate 150. In the display element 10 according to the first embodiment, through holes 115A are formed as the first conductive structures 115.

### (Through Holes)

The through holes 115A as the first conductive structures 115 each have a structure that makes one end 115A1 and the other end 115A2 thereof electrically continuous with each other in the thickness direction (Z-axis direction) of the drive integrated circuit 110. Each through hole 115A extends in the direction from the side of an opposing surface 110A (a so-called active surface) facing the substrate 11 toward the side of a non-opposing surface 110B (the surface opposite to the active surface). The through holes 115A are connected to the wiring lines 113 constituting the drive circuit at the tip portion on the side of the opposing surface 110A, and the tip portion on the side of the non-opposing surface 110B extends to the non-opposing surface 110B of the drive integrated circuit 110 or to a position in the vicinity thereof. In the examples in FIGS. 2 and 3, the through holes 115A are formed as holes penetrating the base substrate 111A. The through holes 115A form through electrodes having conductivity. In a case where the base substrate 111A is a silicon substrate, the through holes 115A are so-called through-silicon vias (TSVs).

The number and the positions of the through holes 115A are determined in accordance with the number and the positions of electrode pads 117 on the side of the non-opposing surface 110B.

The through holes 115A shown as examples in FIGS. 2 and 3 each have a solid structure. Such a through hole 115A can have a structure in which a layer (metal layer) of a metal material is formed inside the hole constituting the through hole 115A, and the inner peripheral surface side of the metal layer is further filled with a metal material of the same type as or a different type from the material of the metal layer, for example. The metal material is not limited to any particular material as long as the metal material is a conductive material, and examples thereof include copper, tungsten, and the like. However, the materials mentioned herein are merely examples. The through holes 115A are only required to be through electrodes, and the structure of each through hole 115A is not limited to any particular one. For example, each through hole 115A may have a hollow structure in which a metal layer is formed inside a hole. The same applies to through holes 136A, first substrate through hole 125A, second substrate through hole 130A, third substrate through hole 145A, and vias 145B, which will be described later.

### (Electrode Pads of the Drive Integrated Circuit)

In the drive integrated circuit 110 illustrated in FIG. 2, electrode pads 116 and 117 are provided on the side of the opposing surface 110A and the side of the non-opposing surface 110B, respectively. The electrode pads 116 provided on the side of the opposing surface 110A are electrically connected to the projecting electrodes 118 on one surface side (second surface side) thereof. Also, the electrode pads 116 are electrically connected to the drive circuit of the drive circuit layer 112 on the other surface side (first surface side).

The structure of each of the electrode pad 116 provided on the side of the opposing surface 110A is not limited to any particular structure, and a metal layer formed with a metal material such as aluminum can be used, for example. In the examples in FIGS. 2 and 3, a plurality of electrode pads 116 on the side of the opposing surface 110A is provided at positions corresponding to the electrode pads 21 of the substrate 11.

The electrode pads 117 provided on the side of the non-opposing surface 110B are electrically connected to the through holes 115A on one surface side (second surface side). Also, the electrode pads 117 are electrically connected to the flexible substrate 150 on the other surface side (first surface side), which is the side of exposed surfaces 117A.

The structure of each of the electrode pads 117 on the side of the non-opposing surface 110B may be a structure similar to that of each electrode pad 116 on the side of the opposing surface 110A. Further, each electrode pads 117 on the side of the non-opposing surface 110B may include a layer formed with a metal material forming the through holes 115A. In this case, the electrode pads 117 may be formed integrally with the through holes 115A. Also, in this case, the electrode pads 117 are preferably subjected to nickel/gold plating on the side of the exposed surfaces 117A. In this manner, stability of the bonding between the electrode pads 117 and the flexible substrate 150 can be enhanced.

### (Projecting Electrodes)

The projecting electrodes 118 are disposed between the substrate 11 and the drive integrated circuit 110. As the projecting electrodes 118, so-called bumps are suitably used. The projecting electrodes 118 are preferably disposed on the electrode pads 116 on the side of the opposing surface 110A of the drive integrated circuit 110. In the example in FIG. 2, the projecting electrodes 118 are disposed on a predetermined region including exposed surfaces 116A of the electrode pads 116, and are electrically connected to the electrode pads 116. The projecting electrodes 118 are preferably structures formed by a method selected from among electrolytic plating, electroless plating, and a stud bump forming method. However, this does not exclude the projecting electrodes 118 being formed by a method other than those methods.

Examples of the material of the projecting electrodes 118 include Au-, Cu-, Al-, Ni-, and Sn-based solder alloys, a stack structure of a plurality of these metals, and the like.

### (Insulating Layer)

An insulating layer 119 is provided on the side of the opposing surface 110A of the drive integrated circuit 110. The insulating layer 119 fills the gaps between the adjacent electrode pads 116 in a planar view of the drive integrated circuit 110. Further, as illustrated in FIG. 2, the insulating layer 119 may be formed so as to protrude onto the surfaces (second surfaces) of the electrode pads 116 so as to cover the outer peripheral edges of the electrode pads 116. However, openings 119A are formed in the insulating layer 119, and the electrode pads 116 are exposed through the openings 119A. The surface portions of the electrode pads 116 exposed through the openings 119A are the exposed surfaces 116A.

(Method of Connection between the Drive Integrated Circuit and the Substrate)

The drive integrated circuit 110 is electrically connected to the circuit of the circuit layer 12 of the substrate 11. The method of connection between the substrate 11 and the drive integrated circuit 110 is not limited to any particular method. Examples of the connection method include a method that uses an anisotropic conductive film 120 (ACF) formed with a resin film containing conductive particles 120A, as illustrated in FIG. 2, for example. This method can be implemented as described below, for example. The drive integrated circuit 110 is positioned so that the projecting electrodes 118 of the drive integrated circuit 110 face the electrode pads 21 on the side of the substrate 11 via the anisotropic conductive film 120. The projecting electrodes 118 and the electrode pads 21 are then pressure-bonded via the anisotropic conductive film 120. At the time of the pressure bonding, the circuit of the substrate 11 and the drive circuit of the drive integrated circuit 110 are electrically connected via the conductive particles 120A contained in the anisotropic conductive film 120. Note that, at this point of time, the surface (active surface) of the drive integrated circuit 110 on which the drive circuit layer 112 is formed is directed to the side of the substrate 11, and the drive integrated circuit 110 is flip-chip mounted on the substrate 11.

Note that the method of connection between the substrate 11 and the drive integrated circuit 110 is not limited to the above method using the anisotropic conductive film 120. As the method of connection between the substrate 11 and the drive integrated circuit 110, a method that uses a non-conductive adhesive film (non-conductive film; NCF) to secure the projecting electrodes 118 and the electrode pads 21 that are connected directly to each other, a method that uses an anisotropic conductive film and a non-conductive adhesive film in combination, solder connection, or the like may be used, for example.

### (Flexible Substrate)

The flexible substrate 150 is a so-called flexible printed circuit board (flexible printed circuits; FPC). The flexible substrate 150 relays electrical connection with an external device or the like. An example of the flexible substrate 150 may be a stack sheet including a base material layer 151, a circuit unit 152 formed on the base material layer 151, and a cover layer 153 covering the circuit unit 152, as illustrated in FIG. 1. An exposed portion 154 is formed in the cover layer 153 at a predetermined position on one end side of the flexible substrate 150. In the flexible substrate 150, wiring portions of the circuit unit 152 are exposed through the exposed portion 154, and the exposed wiring portions serve as connecting terminals 155. The connecting terminals 155 are then electrically connected to the electrode pads 117 on the side of the non-opposing surface 110B of the drive integrated circuit 110. The connecting terminals 155 of the flexible substrate 150 are formed in conformity with the layout of the electrode pads 117 on the side of the non-opposing surface 110B. Note that it is preferable that the flexible substrate 150 has an external connecting terminal (not illustrated) connected to the outside on the end side opposite to the connecting terminals 155 described above. Note that, in FIG. 2 and FIGS. 4 to 9, the base material layer 151, the circuit unit 152, and the cover layer 153 are shown, for ease of explanation.

(Method of Connection between the Flexible Substrate and the Drive Integrated Circuit)

The flexible substrate 150 is disposed on the non-opposing surface 110B that does not face the substrate 11 among the surfaces of the drive integrated circuit 110. In this case, the connecting terminals 155 of the flexible substrate 150 are connected to the electrode pads 117 of the drive integrated circuit 110. The method of connection between the connecting terminals 155 of the flexible substrate 150 and the electrode pads 117 of the drive integrated circuit 110 is not limited to any particular method. As the method of connection between the connecting terminals 155 of the flexible substrate 150 and the electrode pads 117, a method that uses an anisotropic conductive film 121 may be adopted, for example, as in the description of the method of connection between the drive integrated circuit 110 and the substrate 11. This method can be implemented as described below, for example. The connecting terminals 155 of the flexible substrate 150 are made to face the electrode pads 117 of the drive integrated circuit 110. The anisotropic conductive film 121 is interposed between the electrode pads 117 of the drive integrated circuit 110 and the connecting terminals 155 of the flexible substrate 150. The drive integrated circuit 110, the anisotropic conductive film 121, and the flexible substrate 150 are then pressure-bonded to one another, so that the electrode pads 117 are electrically connected to the connecting terminals 155 via conductive particles 121A contained in the anisotropic conductive film 121. As the drive integrated circuit 110 and the flexible substrate 150 are connected in this manner, the circuit unit 152 of the flexible substrate 150 is electrically connected to the through holes 115A corresponding to the first conductive structures 115, and is further electrically connected to the drive circuit layer 112 of the drive integrated circuit 110 via the first conductive structures 115.

### [1-2 Method for Manufacturing the Display Element]

Next, an example of a method for manufacturing the display element 10 according to the first embodiment is described in detail.

### (Preparation of the Substrate)

The base substrate 11A is prepared. The circuit layer 12, the light emitting elements 104, the electrode pads 21, and the like are formed on the base substrate 11A by a technique such as a sputtering method, a lithography method, etching, or a vapor deposition method as necessary, for example. Thus, the substrate 11 can be obtained.

### (Preparation of the Drive Integrated Circuit)

The base substrate 111A is prepared, and the drive circuit layer 112 is formed by a technique similar to that used in the preparation of the substrate 11 as appropriate. The electrode pads 116 are formed on the drive circuit layer 112 by a sputtering method and an etching technique, for example, and the insulating layer 119 is formed so as to fill the gaps between the adjacent electrode pads 116. At this point of time, the electrode pads 116 are exposed through the openings 119A of the insulating layer 119.

The projecting electrodes 118 are formed at the positions where the electrode pads 116 are formed, so as to cover the exposed surfaces 116A of the electrode pads 116. Examples of the method for forming the projecting electrodes 118 include an electrolytic plating method, an electroless plating method, a stud bump forming method, and the like as described above.

The through holes 115A are formed in the drive integrated circuit 110. The method for forming the through holes 115A is not limited to any particular method. For example, a method that can be adopted is a method by which, before or after the drive circuit layer 112 is formed on the base substrate 111A, a structure in which plugs are embedded in the base substrate 111A in a layout corresponding to the layout of the through holes 115A from the side of the surface (the opposing surface 110A) having the drive circuit layer 112 formed thereon is formed by an etching method or the like, and the side of the surface (the non-opposing surface 110B) opposite to the surface having the drive circuit layer 112 formed thereon is ground, to expose the plugs. Other than this method, a method by which plugs are formed in the base substrate 111A from a surface not having the drive circuit layer 112 formed thereon may be used, for example. The plugs are columnar structures extending in the thickness direction of the base substrate 111A, and have conductivity. Examples of the material of the plugs include metal materials such as copper and tungsten.

The electrode pads 117 are formed on the side of the surface of the drive integrated circuit 110 on which the drive circuit layer 112 is not formed. The electrode pads 117 can be formed by a sputtering method and an etching method, for example. The electrode pads 117 are formed in a layout to be in contact with the plugs.

The substrate 11 and the drive integrated circuit 110 are then electrically connected. Also, the drive integrated circuit 110 and the flexible substrate 150 are electrically connected. The methods described above can be used as the method of connection between the substrate 11 and the drive integrated circuit 110, and the method of connection between the drive integrated circuit 110 and the flexible substrate 150. Thus, the display element 10 can be obtained.

### [1-3 Functions and Effects]

In the display element 10 according to the first embodiment, the drive integrated circuit 110 serving as the sub board is provided on the substrate 11 serving as the principal board, and the flexible substrate 150 is further provided on the non-opposing surface 110B (the surface on the side opposite to the active surface) of the drive integrated circuit 110. Thus, according to the first embodiment, the area of the substrate 11 including the light emitting elements 104 can be reduced. Also, in the display element 10 according to the first embodiment, it is easy to form the projecting electrodes 118 as structures of substantially uniform sizes, and the stability of the connection between the substrate 11 and the drive integrated circuit 110 can be enhanced even in a case where the substrate 11 and the drive integrated circuit 110 are connected via the anisotropic conductive film 120. Further, in a case where the drive integrated circuit 110 and the flexible substrate 150 are connected via the anisotropic conductive film 120, the stability of the connection between the drive integrated circuit 110 and the flexible substrate 150 can also be enhanced.

Also, in the display element 10 according to the first embodiment, the transmission distance for an electric signal from the circuit of the flexible substrate 150 to the integrated circuit of the drive integrated circuit 110 can be shortened, and the transmission rate can be increased. Further, in a case where the first conductive structures 115 are the through holes 115A, the through holes 115A easily have structures each having a large cross-sectional area. Accordingly, it is also easy to lower the resistance of the signal transmission path in the display element 10, and thus, the transmission rate can be increased.

### 2 Second Embodiment

### [2-1 Configuration of a Display Element]

A display element 10 according to a second embodiment has a first conductive structure as illustrated in FIG. 4. FIG. 4 is a cross-sectional view schematically illustrating an example of the display element 10 according to the second embodiment. In the second embodiment, the first conductive structure 115 has a side-surface wiring line 115B1 as a wiring line formed on a side surface 110C of a drive integrated circuit 110. The display element 10 according to the second embodiment may be designed in a manner similar to that according to the first embodiment, except for the configuration of the first conductive structures 115. Therefore, in the description of the second embodiment, explanation of the other components except for the configuration of the first conductive structures 115 is not made.

### (First Conductive Structures)

As illustrated in FIG. 4, the first conductive structure 115 includes the side-surface wiring line 115B1. Also, in the example in FIG. 4, the first conductive structure 115 includes, on the side of the opposing surface 110A (the active surface side) with respect to the substrate 11, a wiring line (first coupling wiring line 115B2) that continues to one end of the side-surface wiring line 115B1 and is coupled to an electrode pad 116 on the side of the opposing surface 110A. The first conductive structure 115 includes, on the surface side opposite to the active surface (the side of the non-opposing surface 110B), a wiring line (second coupling wiring line 115B3) that continues to the other end of the side-surface wiring line 115B1 and is coupled to an electrode pad 117 on the side of the non-opposing surface 110B. However, this does not prohibit any case where the first conductive structure 115 excludes at least one of the first coupling wiring line 115B2 and the second coupling wiring line 115B3. The first coupling wiring line 115B2 illustrated in FIG. 4 is connected to a side surface of the electrode pad 116, and the second coupling wiring line 115B3 is interposed between the electrode pad 117 and the base substrate 111A. However, this is merely an example, and the position of connection between the first coupling wiring line 115B2 and the electrode pad 116, and the position of connection between the second coupling wiring line 115B3 and the electrode pad 117 are not limited to this example.

In the first conductive structure 115 illustrated in the example in FIG. 4, the side-surface wiring line 115B1, the first coupling wiring line 115B2, and the second coupling wiring line 115B3 are formed with a metal wiring layer formed on an outer peripheral surface of the drive integrated circuit 110. To form such a metal wiring layer, wiring line formation may be performed after dicing as in a molded interconnect device (MID), for example, or a wafer having a through hole formed therein may be cut along the center portion of the through hole, to obtain individual pieces.

The material of the side-surface wiring line 115B1, the first coupling wiring line 115B2, and the second coupling wiring line 115B3 is not limited to any particular material, and examples thereof may include aluminum, silver, copper, and the like.

In the example of the display element 10 according to the second embodiment illustrated in FIG. 4, the through hole 115A according to the first embodiment is not shown. However, in the display element 10 according to the second embodiment, the through hole 115A may be used in conjunction with the side-surface wiring line 115B1 as the first conductive structure 115.

### [2-2 Functions and Effects]

With the display element 10 according to the second embodiment, effects similar to those of the first embodiment can be achieved.

### 3 Third Embodiment

### [3-1 Configuration of a Display Element]

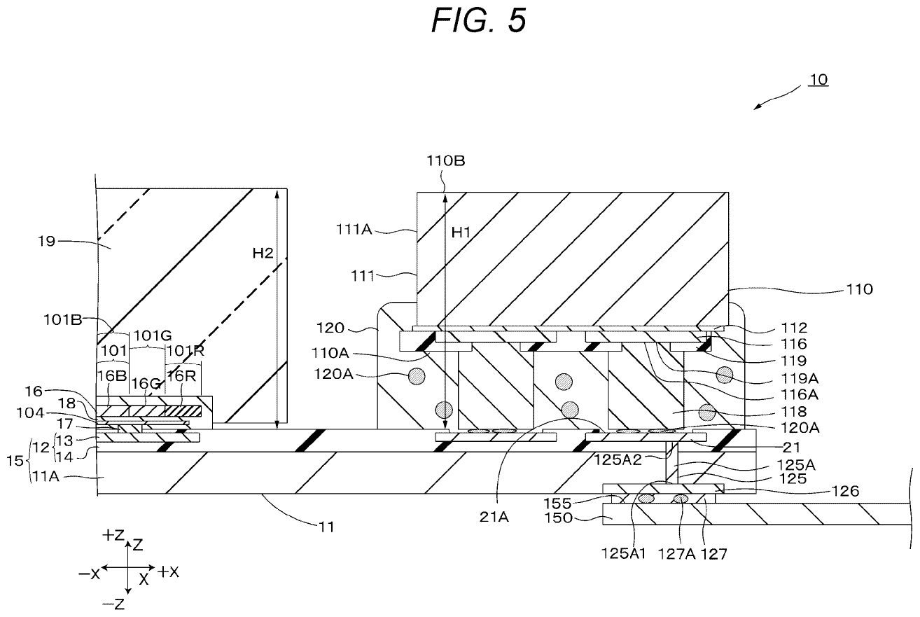

In a display element 10 according to a third embodiment, as illustrated in FIG. 5, a flexible substrate 150 is provided on the surface side (second surface side) opposite to a light emitting surface D among the surfaces of a substrate 11. FIG. 5 is a cross-sectional view schematically illustrating an example of the display element 10 according to the third embodiment. In the third embodiment, second conductive structures 125, and electrode pads 126 connected to the second conductive structures 125 are disposed in the substrate 11, and the flexible substrate 150 is electrically connected to the second conductive structures 125 via the electrode pads 126. Also, in this example, the first conductive structures 115 and the electrode pads 117 described in the first embodiment are not shown. Except for these components, the display element 10 according to the third embodiment may be designed in a manner similar to that according to the first embodiment. Therefore, in the description of the third embodiment, explanation of the other components, except for the configuration of the second conductive structures 125 and the electrode pads 126, and the structure of connection between the flexible substrate 150 and the second conductive structures 125, is not made.

### (Second Conductive Structures)

In the substrate 11, the second conductive structures 125 are disposed at positions corresponding to the positions to which the flexible substrate 150 is connected. The second conductive structures 125 are conductive structures that have conductivity and relay electrical connection with the drive integrated circuit 110. In the display element 10 according to the third embodiment, substrate through holes are formed as the second conductive structures 125. The substrate through holes are called first substrate through holes 125A.

### (Substrate Through Holes)

The first substrate through holes 125A as the second conductive structures 125 each have a structure that makes one end 125A1 and the other end 125A2 of the first substrate through hole 125A electrically continuous with each other in the thickness direction of the substrate 11. The first substrate through holes 125A extend in the direction from the side of the light emitting surface D (first surface side) toward the surface side (second surface side) opposite to the light emitting surface D of the surfaces of the substrate 11. The first substrate through holes 125A are connected to the electrode pads 21 connected to the projecting electrodes 118 of the drive integrated circuit 110 at the end on the side of the light emitting surface D, and are connected to the electrode pads 126 connected to the flexible substrate 150 at the end on the surface side opposite to the light emitting surface D. In the example in FIG. 5, the first substrate through holes 125A are formed as holes penetrating the base substrate 11A, and further continue to the electrode pads 21 through the insulating layer 14.

The first substrate through holes 125A form through electrodes having conductivity. In a case where the base substrate 11A is a silicon substrate, the first substrate through holes 125A are so-called through-silicon vias. The first substrate through holes 125A may have a structure similar to that of the through holes 115A described in the first embodiment. Also, the first substrate through holes 125A can be formed in a manner similar to that for the through holes 115A.

The number and the positions of the first substrate through holes 125A are determined in accordance with the number and the positions of the electrode pads 126.

### (Electrode Pads)

The electrode pads 126 are formed on the second surface side of the substrate 11. The electrode pads 126 are formed in a layout corresponding to the connecting terminals 155 of the flexible substrate 150. The electrode pads 126 are electrically connected to the first substrate through holes 125A. The material of the electrode pads 126 may be similar to the material of the electrode pads 117 on the first surface of the drive integrated circuit 110. Further, the electrode pads 126 may be formed in a manner similar to that for the electrode pads 117.

(Method of Connection between the Flexible Substrate and the Second Conductive Structures)

As the connecting terminals 155 of the flexible substrate 150 are connected to the electrode pads 126, the connecting terminals 155 of the flexible substrate 150 are electrically connected to the second conductive structures 125 of the substrate 11. The method of connection between the connecting terminals 155 of the flexible substrate 150 and the electrode pads 126 is not limited to any particular method. As the method of connection between the connecting terminals 155 and the electrode pads 126, a method that uses an anisotropic conductive film 127 may be adopted, for example, as in the description of the method of connection between the flexible substrate 150 and the drive integrated circuit 110 in the first embodiment. This method can be implemented as described below, for example. The connecting terminals 155 of the flexible substrate 150 are made to face the electrode pads 126 of the substrate 11. The anisotropic conductive film 127 is interposed between the electrode pads 126 and the connecting terminals 155 of the flexible substrate 150. The substrate 11, the anisotropic conductive film 127, and the flexible substrate 150 are then pressure-bonded to one another, so that the electrode pads 126 are electrically connected to the connecting terminals 155 via conductive particles 127A contained in the anisotropic conductive film 127. At this point of time, the circuit of the flexible substrate 150 is electrically connected to the second conductive structures 125, and is further electrically connected to the drive circuit of the drive integrated circuit 110 from the second conductive structures 125 via the projecting electrodes 118.

### [3-2 Method for Manufacturing the Display Element]

Next, an example of a method for manufacturing the display element 10 according to the third embodiment is described.

### (Preparation of the Substrate)

The substrate 11 can be obtained in a manner similar to that in the first embodiment. In the third embodiment, however, the first substrate through holes 125A serving as the second conductive structures 125, and the electrode pads 126 are further formed. For the first substrate through holes, a method similar to the method for forming the through holes 115A explained in the description of the method for manufacturing the display element 10 according to the first embodiment can be used.

### (Preparation of the Drive Integrated Circuit)

The drive integrated circuit 110 can be obtained in a manner similar to that in the first embodiment. In the third embodiment, however, explanation of the method for forming the through holes 115A explained in the description of the method for manufacturing the display element 10 according to the first embodiment is skipped, and explanation of the formation of the electrode pads 117 is skipped.

The projecting electrodes 118 are formed at the positions where the electrode pads 116 are formed, so as to cover the exposed surfaces 116A of the electrode pads 116. Examples of the method for forming the projecting electrodes 118 include an electrolytic plating method, an electroless plating method, a stud bump forming method, and the like as described above.

The substrate 11 and the drive integrated circuit 110 are then electrically connected. The method of connection between the substrate 11 and the drive integrated circuit 110 can be implemented in a manner similar to the method of connection described in the first embodiment. After that, the drive integrated circuit 110 is bonded to the second surface side of the substrate 11, so that the drive integrated circuit 110 and the flexible substrate 150 are electrically connected via the second conductive structures 125. The method of connection between the drive integrated circuit 110 and the flexible substrate 150 via the second conductive structures 125 may be the method described above. Thus, the display element 10 can be obtained.

(Relationship between the Thickness of the Counter Substrate and the Thickness of the Drive Integrated Circuit)

In the display element 10 according to the third embodiment, the counter substrate 19 and the drive integrated circuit 110 are disposed on the same surface side of the substrate 11 (the side of the light emitting surface D in the example in FIG. 5). In the display element 10, with respect to the position in the vertical direction (the thickness direction (Z-axis direction) of the substrate 11), the position of the non-opposing surface 110B that does not face the substrate 11 (the position on the first surface side of the drive integrated circuit 110) among the surfaces of the drive integrated circuit 110, and the position of the exposed surface of the counter substrate 19 (the position on the first surface side of the counter substrate 19) are preferably aligned. In this case, the distance H1 from the first surface (light emitting surface D) of the substrate 11 to the first surface (non-opposing surface 110B) of the drive integrated circuit 110 is substantially equal to the distance H2 from the first surface of the substrate 11 to the first surface (the surface that does not face the light emitting elements 104) of the counter substrate 19. Further, since the thickness of the light emitting elements 104 and the size (height) of the projecting electrodes 118 are normally of very small values with respect to the thicknesses of the counter substrate 19 and the drive integrated circuit 110 in many cases, it is preferable that the thickness of the counter substrate 19 and the thickness of the drive integrated circuit 110 are substantially equal. In the process of manufacturing the display element 10, the drive integrated circuit 110 and the flexible substrate 150 are electrically connected as described above. In this case, the drive integrated circuit 110 and the flexible substrate 150 are normally placed on the same stage. At this point of time, the distance H1 and the distance H2 are almost equal, and thus, the connection between the drive integrated circuit 110 and the flexible substrate 150 via the second conductive structures 125 can be efficiently realized.

### [3-3 Functions and Effects]

In the display element 10 according to the third embodiment, the area of the substrate 11 can be reduced, the stability of the electrical connection between the substrate 11 and the drive integrated circuit 110 can be enhanced, and the stability of the electrical connection between the drive integrated circuit 110 and the flexible substrate 150 can also be enhanced, as in the first embodiment.

Also, in the display element 10 according to the third embodiment, the transmission distance for an electric signal from the circuit of the flexible substrate 150 to the integrated circuit of the drive integrated circuit 110 can be shortened, and the transmission rate can be increased.

### 4 Fourth Embodiment

### [4-1 Configuration of a Display Element]

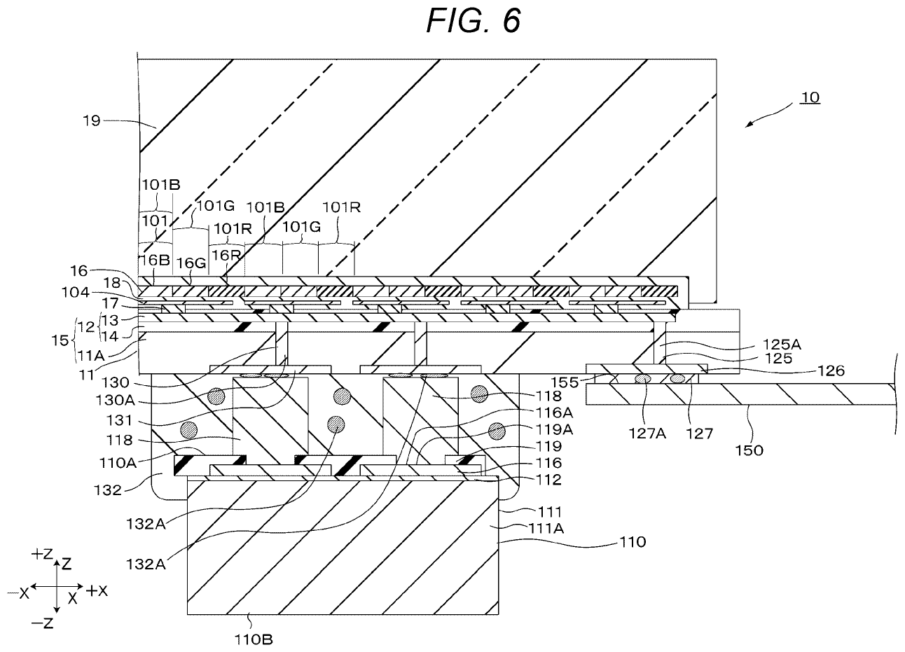

A display element 10 according to a fourth embodiment differs from the display elements according to the first to third embodiments in that the one surface of the substrate 11 on which the drive integrated circuit 110 is disposed is the surface on the side opposite to the light emitting surface D, as illustrated in FIG. 6. That is, the drive integrated circuit 110 is disposed on the surface opposite to the light emitting surface D among the surfaces of the substrate 11. FIG. 6 is a cross-sectional view schematically illustrating an example of the display element 10 according to the fourth embodiment.

In the display element 10 according to the fourth embodiment, third conductive structures 130, and electrode pads 131 connected to the third conductive structures 130 are disposed on the substrate 11, and the drive integrated circuit 110 is electrically connected to the third conductive structures 130 via the electrode pads 131. One end portion of each second conductive structure 125 described in the third embodiment is connected to the flexible substrate 150, but the other end portion of the second conductive structure 125 is electrically connected to the circuit of the circuit layer 12 of the substrate 11. Except for these components, the display element 10 according to the fourth embodiment may be designed in a manner similar to that according to the third embodiment. Therefore, in the description of the fourth embodiment, explanation of the other components, except for the configuration of the third conductive structures 130 and the electrode pads 131, and the structure of connection between the drive integrated circuit 110 and the third conductive structures 130, is not made. Note that, in the fourth embodiment, the first conductive structures 115 described in the first embodiment are not explained, as in the third embodiment. Further, the electrode pads 21 described in the first embodiment are not explained.

### (Third Conductive Structures)

In the substrate 11, the third conductive structures 130 are disposed at positions corresponding to the positions to which the drive integrated circuit 110 is connected. Like the second conductive structures 125 described in the third embodiment, the third conductive structures 130 have conductivity. The third conductive structures 130 are conductive structures that relay electrical connection with the circuit of the substrate 11. In the display element 10 according to the fourth embodiment, substrate through holes are formed as the third conductive structures 130. The substrate through holes are called second substrate through holes 130A.

### (Substrate Through Holes)

The second substrate through holes 130A as the third conductive structures 130 each have a structure that makes one end and the other end of the second substrate through hole 130A electrically continuous with each other in the thickness direction of the substrate 11. Like the first substrate through holes 125A described in the third embodiment, the second substrate through holes 130A extend in the direction from the side of the light emitting surface D (first surface side) toward the surface side (second surface side) opposite to the light emitting surface D of the surfaces of the substrate 11. The second substrate through holes 130A are connected to the circuit of the circuit layer 12 at the end on the side of the light emitting surface D, and are connected to the projecting electrodes 118 of the drive integrated circuit 110 via the electrode pads 131 at the end on the surface side opposite to the light emitting surface D. In the example in FIG. 5, the second substrate through holes 130A are formed as holes penetrating the base substrate 11A. In the fourth embodiment, the first substrate through holes 125A described above in the third embodiment, and the second substrate through holes 130A are formed as substrate through holes in the substrate 11. However, the first substrate through holes 125A are connected to the connecting terminals 155 of the flexible substrate 150 at the end on the surface side opposite to the light emitting surface D, but, unlike those in the case of the third embodiment, the first substrate through holes 125A are connected to the circuit of the circuit layer 12 at the end on the side of the light emitting surface D.

The second substrate through holes 130A form through electrodes having conductivity. Like the first substrate through holes 125A described in the third embodiment, the second substrate through holes 130A are so-called through-silicon vias in a case where the base substrate 11A is a silicon substrate. Like the first substrate through holes 125A, each of the second substrate through holes 130A may have a structure similar to that of the through holes 115A described in the first embodiment. Also, the second substrate through holes 130A can be formed in a manner similar to that for the through holes 115A.

The number and the positions of the second substrate through holes 130A are determined in accordance with the number and the positions of the electrode pads 131.

### (Electrode Pads)

In addition to the electrode pads 126, the electrode pads 131 are formed on the second surface side of the substrate 11. The electrode pads 131 are formed in a layout corresponding to the projecting electrodes 118 of the drive integrated circuit 110. The electrode pads 131 are electrically connected to the second substrate through holes 130A. The material of the electrode pads 131 may be similar to the material of the electrode pads 126. Further, the electrode pads 131 may be formed in a manner similar to that for the electrode pads 126.

(Method of Connection between the Drive Integrated Circuit and the Third Conductive Structures)

As the projecting electrodes 118 of the drive integrated circuit 110 are connected to the electrode pads 131, the drive integrated circuit 110 is electrically connected to the third conductive structures 130. The method of connection between the projecting electrodes 118 of the drive integrated circuit 110 and the electrode pads 131 is not limited to any particular method. As the method of connection between the projecting electrodes 118 of the drive integrated circuit 110 and the electrode pads 131, a method that uses an anisotropic conductive film 132 may be adopted, for example, as in the description of the method of connection between the drive integrated circuit 110 and the substrate 11 in the first embodiment. This method can be implemented as described below, for example. The projecting electrodes 118 of the drive integrated circuit 110 are made to face the electrode pads 131 of the substrate 11. The anisotropic conductive film 132 is interposed between the substrate 11 and the drive integrated circuit 110, which are then pressure-bonded to each other, so that the electrode pads 131 are electrically connected to the projecting electrodes 118 via conductive particles 132A contained in the anisotropic conductive film 132. As the electrode pads 131 of the substrate 11 are connected to the drive integrated circuit 110 in this manner, the drive circuit of the drive integrated circuit 110 is electrically connected to the third conductive structures 130, and is further electrically connected from the third conductive structures 130 to the circuit forming the circuit layer 12 of the substrate 11.

### [4-2 Functions and Effects]

In the display element 10 according to the fourth embodiment, the area of the substrate 11 can be reduced, the stability of the connection between the substrate 11 and the drive integrated circuit 110 can be enhanced, and the stability of the connection between the drive integrated circuit 110 and the flexible substrate 150 can also be enhanced, as in the first embodiment. The number of channels between the drive integrated circuit 110 and the display element 10 can be increased, and the transmission rate can be made higher.

### 5 Fifth Embodiment

### [5-1 Configuration of a Display Element]

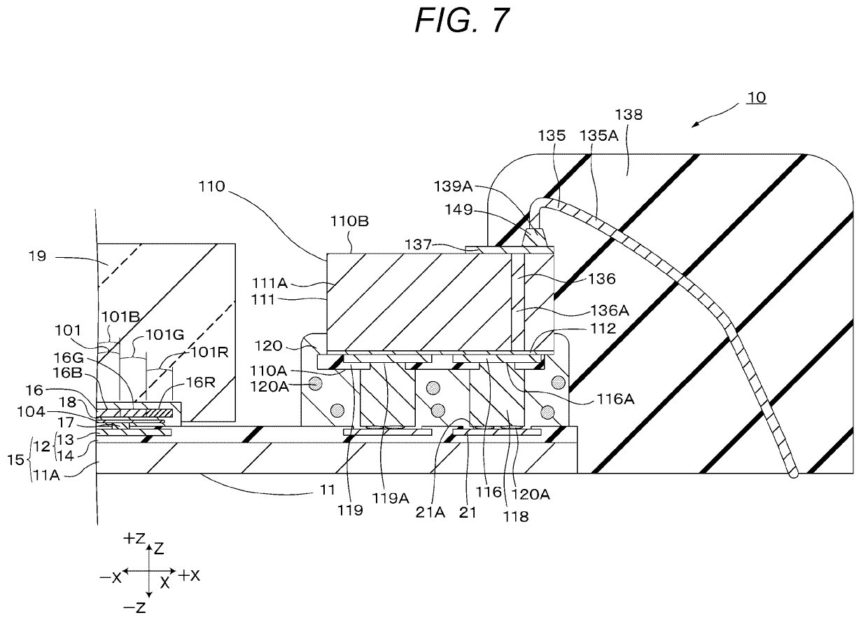

As illustrated in FIG. 7, a display element 10 according to a fifth embodiment includes conductive connecting members 135 that relay electrical connection with the outside. FIG. 7 is a cross-sectional view illustrating an example of the display element 10 according to the fifth embodiment. The display element 10 according to the fifth embodiment includes a drive integrated circuit 110. The drive integrated circuit 110 has fourth conductive structures 136 as conductive structures that relay electrical connection with the drive circuit. The fourth conductive structures 136 of the drive integrated circuit 110 are electrically connected to the conductive connecting members 135. Except for these aspects, the display element 10 according to the fifth embodiment is formed in a manner similar to that according to the first embodiment. Therefore, detailed explanation of other components, except for the conductive connecting members 135, the fourth conductive structures 136, and the structure of connection between the conductive connecting members 135 and the drive integrated circuit 110, is not made herein. Note that, like the display element 10 according to the first embodiment, the display element 10 according to the fifth embodiment has a structure in which the drive integrated circuit 110 is disposed on one surface (on the light emitting surface D) of the substrate 11.

### (Conductive Connecting Members)

The conductive connecting members 135 are conductive members that relay electrical connection with the outside. One end of each conductive connecting member 135 is located on the non-opposing surface 110B not facing the substrate 11 among the surfaces of the drive integrated circuit 110. The conductive connecting members 135 are members different from the flexible substrate 150, and are wires 135A in the example illustrated in FIG. 7. FIG. 7 is an example, and does not prohibit any case where the conductive connecting members 135 differ from the wires 135A. In the description of the fifth embodiment, however, a case where the conductive connecting members 135 are the wires 135A is explained as an example.

### (Wires)

In the example in FIG. 7, each wire 135A is electrically connected to an electrode pad of the drive integrated circuit on one end side thereof. The material of the wires 135A is not limited to any particular material, and a metal material such as silver, gold, or copper can be used. The wires 135A are normally connected to the respective electrode pads 137, in accordance with the layout of the electrode pads.

### (Fourth Conductive Structures)

The fourth conductive structures 136 that relay electrical connection with the conductive connecting members 135 are provided in the drive integrated circuit 110. The fourth conductive structures 136 may be formed in a manner similar to that for the first conductive structures 115 formed in the display element 10 according to the first embodiment. The fourth conductive structures 136 are disposed in the drive integrated circuit 110, and electrically connect the conductive connecting members 135 to the drive circuit. In the display element 10 according to the fifth embodiment, through holes 136A are formed as the fourth conductive structures 136, as illustrated in FIG. 7. Each through hole 136A has a structure that makes one end and the other end electrically continuous with each other in the thickness direction of the drive integrated circuit 110. Each through hole 136A may have the same structure as the through holes 115A formed as the first conductive structures 115.

### (Electrode Pads)

In the fifth embodiment, like the electrode pads 117 of the first embodiment, the electrode pads 137 are formed on the non-opposing surface 110B (the surface on the side opposite to the surface facing the light emitting surface D) of the drive integrated circuit 110, and the electrode pads 137 are electrically connected to the through holes 136A. The electrode pads 137 may be formed with a material similar to that of the electrode pads 117. Further, the electrode pads 137 may be formed in a manner similar to that for the electrode pads 117.

(Method of Connection between the Conductive Connecting Members and the Drive Integrated Circuit)

The method of electrical connection between the conductive connecting members 135 and the drive integrated circuit 110 is not limited to any particular method. However, in a case where the conductive connecting members 135 are the wires 135A as illustrated in FIG. 7, wire bonding can be adopted as an example of the method of electrical connection between the conductive connecting members 135 and the drive integrated circuit. In this case, one end portion of each wire 135A is secured onto the corresponding electrode pad 137 by a wire bonding method. Note that, in FIG. 7, reference numeral 149 indicates a bonding material for securing the wire 135A to the electrode pad 137. The portion fixed by the bonding material 149 is a connecting portion 139A.

### (Sealing Layer)

In the display element 10 according to the fifth embodiment, a sealing layer 138 is preferably provided as illustrated in FIG. 7, for example. The sealing layer 138 covers the connecting portions 139A between the conductive connecting members 135 and the drive integrated circuit 110. In the example in FIG. 7, the sealing layer 138 covers the connecting portions 139A and the wires 135A. The sealing layer 138 reduces breakage of the connecting portions 139A and disconnection of the wires 135A. The material of the sealing layer 138 may be a resin material or the like, for example.

### [5-2 Functions and Effects]

With the display element 10 according to the fifth embodiment, effects similar to those of the first embodiment can be achieved.

A modification of the display element 10 according to the fifth embodiment is now described.

### [5-3 Modification]

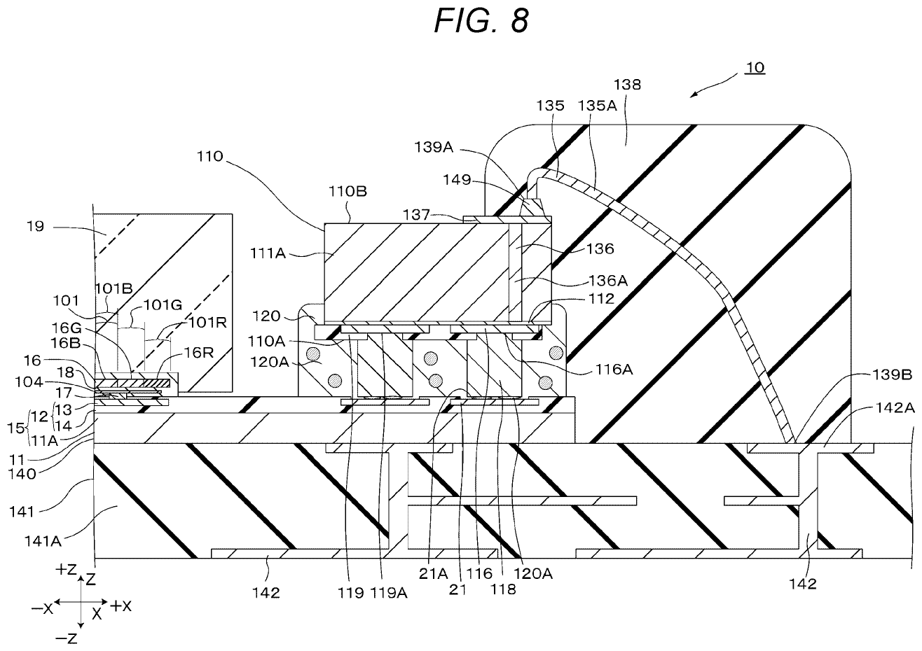

As illustrated in FIG. 8, a display element 10 according to a modification of the fifth embodiment includes a first substrate 140 formed with the substrate 11 and a second substrate 141 different from the first substrate 140, and the other end of each conductive connecting member 135 is electrically connected to the second substrate 141. FIG. 8 is a cross-sectional view illustrating an example of the display element 10 according to the modification of the fifth embodiment. FIG. 8 also illustrates an example of the display element 10 in a case where the conductive connecting members 135 are the wires 135A.

### (Second Substrate)

As illustrated in FIG. 8, the second substrate 141 is a printed wiring board in which a circuit is formed in a base substrate 141A. In FIG. 8, as for the second substrate 141, some of the wiring lines 142 forming the circuit are shown, and a view of the entire circuit is not shown. More specifically, the second substrate may be a so-called motherboard or the like, for example. The second substrate 141 is a substrate different from the flexible substrate 150 described above. The second substrate 141 may be a rigid substrate, for example. The second substrate 141 is bonded to the surface (second surface) of the first substrate 140 on the side opposite to the light emitting surface D. The method of bonding between the second substrate 141 and the first substrate 140 is not limited to any particular method, and may be a die bonding method or the like, for example.

(Method of Connection between the Conductive Connecting Members and the Second Substrate)

One end side of each conductive connecting member 135 is electrically connected to the drive integrated circuit 110, and the other end side is electrically connected to the second substrate 141. The method of electrical connection between the conductive connecting members 135 and second substrate 141 is not limited to any particular method. As illustrated in FIG. 8, in a case where the conductive connecting members 135 are the wires 135A, the wires 135A and second substrate 141 may be electrically connected by a wire bonding method. In the example in FIG. 8, conductive connecting terminals 142A formed with wiring lines 142 formed in the circuit of the second substrate 141 are exposed through the side of the opposing surface (first surface side) facing the first substrate 140 among the surfaces of the second substrate 141. The other end of each wire 135A is then electrically connected to the corresponding connecting terminal 142A of the second substrate 141 by a wire bonding method. Note that, as illustrated in FIG. 8, in the display element 10 according to the modification of the fifth embodiment, both the connecting portions 139A between the wires 135A and the drive integrated circuit 110, and connecting portions 139B between the wires 135A and the second substrate 141 are preferably sealed with the sealing layer 138.

### 6 Sixth Embodiment

### [6-1 Configuration of a Display Element]

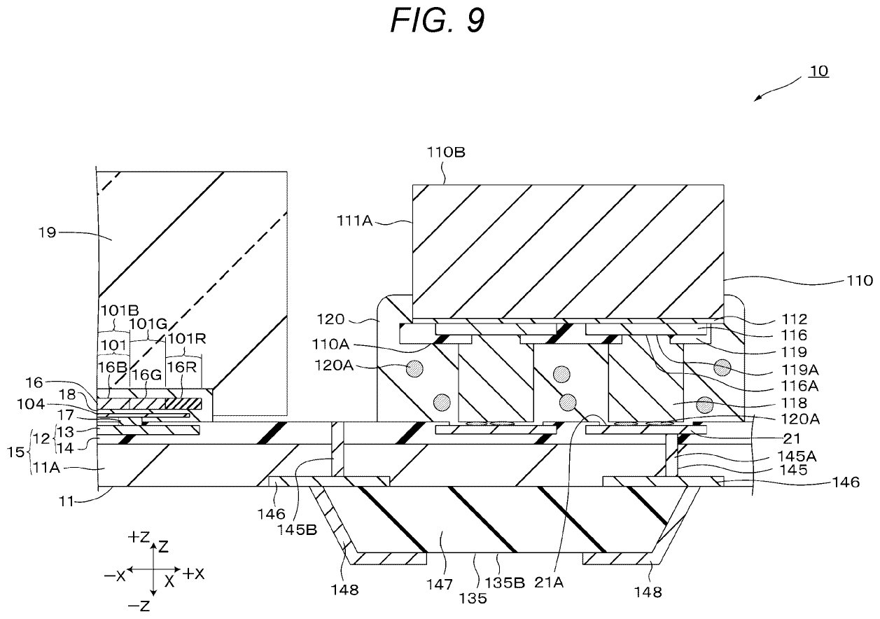

In a display element 10 according to a sixth embodiment, as illustrated in FIG. 9, conductive connecting members 135 are provided on the surface side (second surface side) opposite to a light emitting surface D among the surfaces of a substrate 11. FIG. 9 is a cross-sectional view schematically illustrating an example of the display element 10 according to the sixth embodiment.

In the sixth embodiment, fifth conductive structures 145, and electrode pads 146 connected to the fifth conductive structures 145 are disposed in the substrate 11, and the conductive connecting members 135 are electrically connected to the fifth conductive structures 145 via the electrode pads 146. In the example illustrated in FIG. 9, the conductive connecting members 135 are connectors 135B. Also, in this example, the fourth conductive structures 136 provided in the fifth embodiment, and the sealing layer 138 provided as appropriate are not shown. Except for these components, the display element 10 according to the sixth embodiment may be designed in a manner similar to that according to the fifth embodiment. Therefore, in the description of the sixth embodiment, explanation of the other components, except for the configuration of the conductive connecting members 135, the fifth conductive structures 145, and the electrode pads 146, and the structure of connection between the conductive connecting members 135 and the fifth conductive structures 145, is not made.

### (Conductive Connecting Members)

As described in the fifth embodiment, the conductive connecting members 135 are conductive connecting members that relay electrical connection with the outside. The conductive connecting members 135 are members different from the flexible substrate 150, and are the connectors 135B in the example illustrated in FIG. 9. FIG. 9 is an example, and does not prohibit any case where the conductive connecting members 135 differ from the connectors 135B. In the description of the sixth embodiment, however, explanation of an example case where the conductive connecting members 135 are the connectors 135B is continued.

### (Connectors)

In the example in FIG. 9, a connector 135B includes a body 147, and a wiring line 148 disposed on the outer peripheral surface of the body 147. The material of the wiring line 148 is not limited to any particular material, and a metal material such as silver, gold, or copper can be used. The wiring line 148 continuously extends on the side surface of the substrate 11 from the side of the non-opposing surface (second surface side) not facing the substrate 11 among the surfaces of the body 147, toward the side of the surface facing the substrate 11. In the connector 135B, an end portion of the wiring line 148 extending toward the side of the surface facing the substrate 11 is electrically connected to an electrode pad 146 of the substrate 11. The shape of the body 147 of the connector 135B is not limited, and is formed to have a trapezoidal cross-sectional shape in the example in FIG. 9. Further, the material of the body 147 of the connector 135B is preferably formed with an insulating material, and specifically, may be a resin material or the like, for example.

### (Fifth Conductive Structures)

In the substrate 11, the fifth conductive structures 145 are provided as conductive structures at the positions corresponding to the positions to which the connectors 135B as an example of the conductive connecting members 135 are connected. The fifth conductive structures 145 may be the same structures as the second conductive structures 125 described in the third embodiment. The fifth conductive structures 145 may be formed with a material similar to and by a method similar to those for the second conductive structures 125. Each fifth conductive structure 145 has a structure that makes one end and the other end electrically continuous with each other in the thickness direction of the substrate 11. In the example in FIG. 9, substrate through holes (referred to as third substrate through holes 145A) having the same structure as the second conductive structures 125 are provided in the fifth conductive structures 145. Note that, as illustrated in FIG. 9, unlike the second conductive structures 125, the fifth conductive structures 145 may be formed with holes (vias 145B) that are electrically disconnected from the electrode pads 21 connected to the drive integrated circuit 110, and have conductivity.

### (Electrode Pads)

The electrode pads 146 are formed on the second surface side of the substrate 11. The electrode pads 146 may be formed with a material similar to and by a method similar to those for the electrode pads 126 described in the third embodiment.

(Method of Connection between the Conductive Connecting Members and the Fifth Conductive Structures)

As the wiring lines 148 of the conductive connecting members 135 are connected to the electrode pads 146, the wiring lines 148 are electrically connected to the fifth conductive structures 145 of the substrate 11. The method of connection between the wiring lines 148 of the conductive connecting members 135 and the electrode pads 146 is not limited to any particular method. The method of connection between the wiring lines 148 of the conductive connecting members 135 and the electrode pads 146 may be a die bonding method or the like.

### [6-2 Functions and Effects]

In the display element 10 according to the sixth embodiment, the area of the substrate 11 can be reduced, as in the first embodiment.

Also, in the display element 10 according to the sixth embodiment, the transmission distance for an electric signal from the conductive connecting members 135 such as the connectors 135B to the integrated circuit of the drive integrated circuit 110 can be shortened, and the transmission rate can be made higher.

### 7 Example Applications

### (Electronic Devices)

A display element 10 according to the present disclosure may be included in various electronic devices. For example, a display element (display element 10) according to one of the embodiments (any one of the first to sixth embodiments) described above may be included in various electronic devices. Especially, a display element according to one of the above embodiments is preferably included in an electronic viewfinder of a video camera or a single-lens reflex camera, a head mounted display, or the like in which high resolution is required, used for enlarging near the eyes.

### Specific Example 1

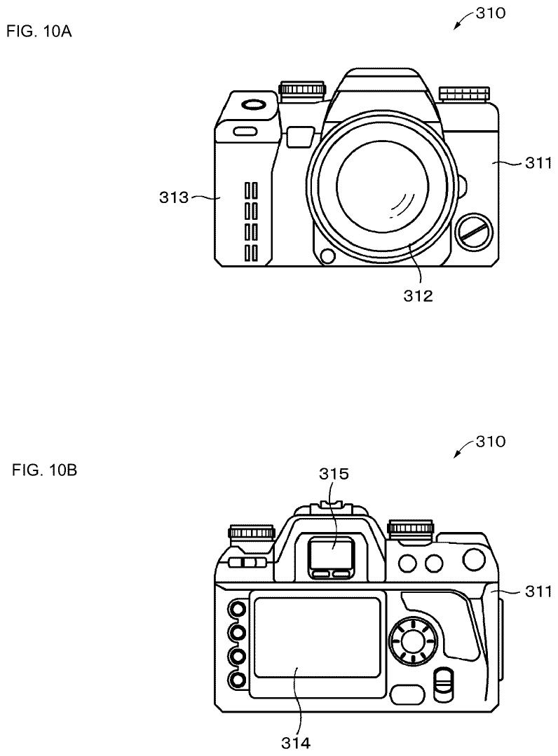

FIG. 10A is a front view illustrating an example of an external appearance of a digital still camera 310. FIG. 10B is a rear view illustrating an example of an external appearance of the digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip 313 to be held by the photographer on the front left side.

A monitor 314 is provided at a position shifted to the left side from the center of the rear surface of the camera main body 311. An electronic viewfinder (eyepiece window) 315 is provided above the monitor 314. By looking through the electronic viewfinder 315, the photographer can visually recognize an optical image of the subject guided from the imaging lens unit 312, and determine a picture composition. As the electronic viewfinder 315, a display element 10 according to any one of the above embodiments and modifications thereof can be used.

### Specific Example 2

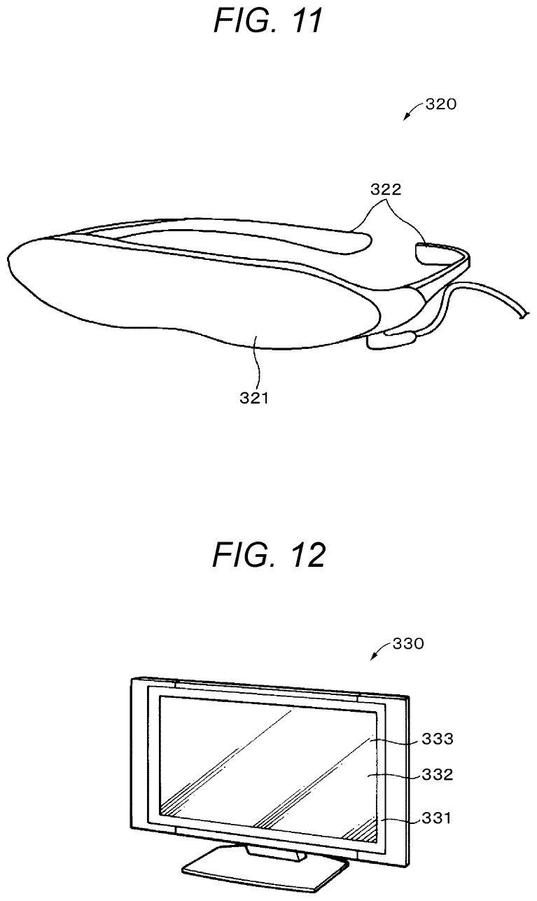

FIG. 11 is a perspective view illustrating an example of an external appearance of a head-mounted display 320. The head-mounted display 320 includes ear hooking portions 322 to be worn on the head of the user on both sides of a display unit 321 in the shape of eyeglasses, for example. As the display unit 321, a display element 10 according to any one of the above embodiments and modifications thereof can be used.

### Specific Example 3

FIG. 12 is a perspective view illustrating an example of an external appearance of a television device 330. The television device 330 includes a video display screen unit 331 including a front panel 332 and a filter glass 333, and the video display screen unit 331 is formed with a display element 10 according to any one of the above embodiments and modifications thereof, for example.

The display elements according to the first to sixth embodiments of the present disclosure and the modifications of the embodiments, and the example applications have been specifically described so far. However, the present disclosure is not limited to the display elements according to the first to sixth embodiments and the modifications thereof, and the example applications described above, and various modifications based on the technical idea of the present disclosure can be made.

For example, the configurations, methods, steps, shapes, materials, numerical values, and the like given in the display elements according to the first to sixth embodiments and the modifications thereof, and the example applications are merely examples, and different configurations, methods, steps, shapes, materials, numerical values, and the like may be used as necessary.

The configurations, methods, steps, shapes, materials, numerical values, and the like of the display elements according to the first to sixth embodiments and the modifications thereof, and the example applications can be combined with one another without departing from the gist of the present disclosure.

The materials mentioned as examples in the display elements according to the first to sixth embodiments and the modifications thereof, and the example applications can be used independently of one another or in combination of two or more, unless otherwise specified.

Further, the present disclosure can also adopt the following configurations.
(1) A display element including:
a substrate that includes a light emitting element disposed therein, and has a light emitting surface;
a drive integrated circuit including a drive circuit that controls driving of the light emitting element; and
a flexible substrate having a connecting terminal, in which the drive integrated circuit is disposed on one surface of the substrate, and
the flexible substrate is disposed on a surface of the drive integrated circuit, the surface not facing the substrate.

(2) The display element of (1), in which
a first conductive structure that relays electrical connection with the drive circuit is disposed in the drive integrated circuit, and
the flexible substrate is electrically connected to the first conductive structure.

(3) The display element of (2), in which
the first conductive structure includes a through hole that has conductivity and is electrically continuous in a thickness direction of the drive integrated circuit.

(4) The display element of (2), in which
the first conductive structure includes a wiring line formed on a side surface of the drive integrated circuit.

(5) The display element of any one of (1) to (4), in which
the drive integrated circuit is formed with a sub board on which the drive circuit is mounted.

(6) A display element including:
a substrate that includes a light emitting element disposed therein, and has a light emitting surface;
a drive integrated circuit including a drive circuit that controls driving of the light emitting element; and
a flexible substrate,
in which the drive integrated circuit is disposed on one surface of the substrate, and
the flexible substrate is disposed on a surface of the substrate, the surface being opposite to the light emitting surface.

(7) The display element of (6), in which
a second conductive structure that relays electrical connection with the drive integrated circuit is disposed in the substrate, and
the flexible substrate is electrically connected to the second conductive structure.

(8) The display element of (7), in which
the second conductive structure includes a first substrate through hole that has conductivity and is electrically continuous in a thickness direction of the substrate.

(9) The display element of any one of (6) to (8), in which
a counter substrate that covers the light emitting surface of the substrate is provided, and
the drive integrated circuit is disposed on a side of the light emitting surface of the substrate, and
a position of a surface not facing the substrate among surfaces of the drive integrated circuit is aligned with a position of an exposed surface of the counter substrate.

(10) The display element of any one of (6) to (8), in which
the drive integrated circuit is disposed on a surface of the substrate, the surface being opposite to the light emitting surface.

(11) The display element of (10), in which
the substrate includes a circuit,
a third conductive structure that relays electrical connection with the circuit is disposed in the substrate, and
the drive integrated circuit is electrically connected to the third conductive structure.

(12) The display element of (11), in which
the third conductive structure includes a second substrate through hole that has conductivity and is electrically continuous in a thickness direction of the substrate.

(13) A display element including:
a substrate that includes a light emitting element disposed therein, and has a light emitting surface;
a drive integrated circuit including a drive circuit that controls driving of the light emitting element; and
a conductive connecting member that relays electrical connection with outside,
in which the drive integrated circuit is disposed on one surface of the substrate, and
the conductive connecting member is disposed on a surface of the drive integrated circuit, the surface not facing the substrate.

(14) The display element of (13), in which
a fourth conductive structure that relays electrical connection with the drive circuit is disposed in the drive integrated circuit, and
the conductive connecting member is electrically connected to the fourth conductive structure.

(15) The display element of (14), in which
the fourth conductive structure includes a through hole that has conductivity and is electrically continuous in a thickness direction of the drive integrated circuit.

(16) The display element of any one of (13) to (15), in which
the conductive connecting member includes a wire.

(17) The display element of any one of (13) to (16), including:
a first substrate formed with the substrate; and
a second substrate that is different from the first substrate, and is disposed on a side of a surface opposite to the side of the light emitting surface with respect to the first substrate,
in which one end of the conductive connecting member is electrically connected to the drive integrated circuit, and the other end of the conductive connecting member is electrically connected to the second substrate.

(18) A display element including:
a substrate that includes a light emitting element disposed therein;
a drive integrated circuit including a drive circuit that controls driving of the light emitting element; and
a conductive connecting member that relays electrical connection with outside,
in which the drive integrated circuit is disposed on one surface of the substrate, and
the conductive connecting member is disposed on a side of a surface of the substrate, the surface being opposite to a light emitting surface.

(19) The display element of (18), in which
a fifth conductive structure that relays electrical connection with the drive integrated circuit is disposed in the substrate, and
the conductive connecting member is electrically connected to the fifth conductive structure.

(20) The display element of (19), in which
the fifth conductive structure includes a substrate through hole that has conductivity and is electrically continuous in a thickness direction of the substrate.

(21) The display element of any one of (18) to (20), in which
the conductive connecting member is a connector.

(22) An electronic device including
the display element of any one of (1) to (21).

### REFERENCE SIGNS LIST

10 Display element
11 Substrate
19 Counter substrate
104 Light emitting element
110 Drive integrated circuit
110A Opposing surface
110B Non-opposing surface
110C Side surface
111 Substrate
113 Wiring line
115 First conductive structure
115A Through hole
115B1 Side-surface wiring line
115B2 First coupling wiring line
115B3 Second coupling wiring line
116 Electrode pad
117A Exposed surface
118 Projecting electrode
120 Anisotropic conductive film
120A Conductive particles
121 Anisotropic conductive film
121A Conductive particles
125 Second conductive structure
125A First substrate through hole
130 Third conductive structure
130A Second substrate through hole
135 Conductive connecting member
135A Wire
135B Connector
136 Fourth conductive structure
136A Through hole
138 Sealing layer
139A Connecting portion
140 First substrate
141 Second substrate
142 Wiring line
145 Fifth conductive structure
145A Third substrate through hole
150 Flexible substrate
155 Connecting terminal
310 Digital still camera
320 Head-mounted display
330 Television device

1. A display element comprising:
a substrate that includes a light emitting element disposed therein, and has a light emitting surface;
a drive integrated circuit including a drive circuit that controls driving of the light emitting element; and
a flexible substrate,
wherein the drive integrated circuit is disposed on one surface of the substrate, and
the flexible substrate is disposed on a surface of the drive integrated circuit, the surface not facing the substrate.

2. The display element according to claim 1, wherein
a first conductive structure that relays electrical connection with the drive circuit is disposed in the drive integrated circuit, and
the flexible substrate is electrically connected to the first conductive structure.

3. The display element according to claim 2, wherein
the first conductive structure includes a through hole that has conductivity and is electrically continuous in a thickness direction of the drive integrated circuit.

4. The display element according to claim 2, wherein
the first conductive structure includes a wiring line formed on a side surface of the drive integrated circuit.

5. The display element according to claim 1, wherein
the drive integrated circuit is formed with a sub board on which the drive circuit is mounted.

6. A display element comprising:
a substrate that includes a light emitting element disposed therein, and has a light emitting surface;
a drive integrated circuit including a drive circuit that controls driving of the light emitting element; and
a flexible substrate,
wherein the drive integrated circuit is disposed on one surface of the substrate, and
the flexible substrate is disposed on a surface of the substrate, the surface being opposite to the light emitting surface.

7. The display element according to claim 6, wherein
a second conductive structure that relays electrical connection with the drive integrated circuit is disposed in the substrate, and
the flexible substrate is electrically connected to the second conductive structure.

8. The display element according to claim 7, wherein
the second conductive structure includes a first substrate through hole that has conductivity and is electrically continuous in a thickness direction of the substrate.

9. The display element according to claim 6, wherein
a counter substrate that covers the light emitting surface of the substrate is provided, and
the drive integrated circuit is disposed on a side of the light emitting surface of the substrate, and
a position of a surface not facing the substrate among surfaces of the drive integrated circuit is aligned with a position of an exposed surface of the counter substrate.

10. The display element according to claim 6, wherein
the drive integrated circuit is disposed on a surface of the substrate, the surface being opposite to the light emitting surface.

11. The display element according to claim 10, wherein
the substrate includes a circuit,
a third conductive structure that relays electrical connection with the circuit is disposed in the substrate, and
the drive integrated circuit is electrically connected to the third conductive structure.

12. The display element according to claim 11, wherein
the third conductive structure includes a second substrate through hole that has conductivity and is electrically continuous in a thickness direction of the substrate.

13. A display element comprising:
a substrate that includes a light emitting element disposed therein, and has a light emitting surface;
a drive integrated circuit including a drive circuit that controls driving of the light emitting element; and
a conductive connecting member that relays electrical connection with outside,
wherein the drive integrated circuit is disposed on one surface of the substrate, and
the conductive connecting member is disposed on a surface of the drive integrated circuit, the surface not facing the substrate.

14. The display element according to claim 13, wherein
a fourth conductive structure that relays electrical connection with the drive circuit is disposed in the drive integrated circuit, and
the conductive connecting member is electrically connected to the fourth conductive structure.

15. The display element according to claim 14, wherein
the fourth conductive structure includes a through hole that has conductivity and is electrically continuous in a thickness direction of the drive integrated circuit.

16. The display element according to claim 13, wherein
the conductive connecting member includes a wire.

17. The display element according to claim 13, further comprising:
a first substrate formed with the substrate; and
a second substrate that is different from the first substrate, and is disposed on a side of a surface opposite to a side of the light emitting surface with respect to the first substrate,
wherein one end of the conductive connecting member is electrically connected to the drive integrated circuit, and another end of the conductive connecting member is electrically connected to the second substrate.

18. An electronic device comprising
the display element according to claim 1.
